(19) United States
(12) Patent Application Publication
(10) Pub. No.: US 2010/0252103 A1
(43) Pub. Date: Oct. 7, 2010

(54) PHOTOELECTRONIC ELEMENT HAVING A TRANSPARENT ADHESION STRUCTURE AND THE MANUFACTURING METHOD THEREOF

(76) Inventors: Chiu-Lin YAO, Hsinchu (TW); Ying-Yong SU, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/753,589

(22) Filed: Apr. 2, 2010

(30) Foreign Application Priority Data
Apr. 3, 2009 (TW) 098111428
Apr. 28, 2009 (CN) 200910132205.4

(51) Int. Cl. H01L 31/042; H01L 31/18

(52) U.S. Cl. 136/256; 438/64; 257/E31.119

(57) ABSTRACT

A photoelectronic element having a transparent adhesion structure includes a supporting substrate; a first transparent adhesion layer formed on the supporting substrate; a second transparent adhesion layer formed on the first transparent adhesion layer; and a first semiconductor stack layer formed on the second transparent adhesion layer wherein the first semiconductor stack layer includes a first active layer; wherein the interface between the first transparent adhesion layer and the second transparent adhesion layer contains hydrogen-oxygen bond after being treated by an activator.

### TECHNICAL FIELD

The application relates to a photoelectronic element, and more particularly to a light-emitting element including a transparent adhesion structure.

### REFERENCE TO RELATED APPLICATION

The application claims the right of priority based on TW application Ser. No. 098111428 filed on Apr. 3, 2009, which is incorporated herein by reference and assigned to the assignee herein.

### DESCRIPTION OF BACKGROUND ART

There are various kinds of photoelectronic elements. For example, light-emitting diode (LED), solar cell, photo diode and so on. Take LED for example, LED is a solid-state semiconductor element including one p-n junction. The p-n junction is formed between the p-type semiconductor layer and the n-type semiconductor layer. When a bias voltage over certain level is applied to the p-n junction, the holes in the p-type semiconductor layer and the electrons in the n-type semiconductor combines and emits light. The region where the light emits is also called the light-emitting region.

The main features of LED are small size, high light-emitting efficiency, long life-time, fast response, high reliability and good hues. LED is generally used in electronic equipments, automobiles, signboards and traffic signals. As the full color LED being presented to the public, the conventional lighting apparatus such as fluorescent lamps and incandescent lamps are replaced by LED gradually.

Because of the shortage of the petrochemical energy and the raising of the environmental protection consciousness, people continuously develop the technologies related to the substituted energy and the recyclable energy in the recent years and hope to decrease the dependence on the petrochemical energy and the influence on the environment while using the petrochemical energy. Among the numerous technologies related to the substituted energy and the recyclable energy, solar cell is the most noticed one. It is mainly because the solar cell produces no harmful substances such as carbon dioxide and nitrides during the conversion process while converting the solar energy into the electric energy directly, and does not contaminate the environment.

The aforementioned photoelectronic elements further form the lighting apparatus or the light-absorbing apparatus by connecting the substrate and a base with a bumping material or glue. Besides, the base further includes one circuit electrically connecting to the electrodes of the photoelectronic elements through a conductive structure such as a metal wire.

### SUMMARY OF THE DISCLOSURE

The steps of a manufacture method in accordance with the first embodiment of present application include providing a first semiconductor stack layer including a first active layer; providing a supporting substrate; forming a first transparent adhesion layer on the supporting substrate; forming a second transparent adhesion layer under a first surface of the first semiconductor stack layer; flatting the surfaces of the first transparent adhesion layer and the second transparent adhesion layer; treating the flatted surfaces of the first transparent adhesion layer and the second transparent adhesion layer with an activator, wherein the flatted surfaces of the first transparent adhesion layer and the second transparent adhesion layer contains hydrogen-oxygen bonds after being treated by the activator; performing a connecting process including connecting the first semiconductor stack layer with the supporting substrate by the first transparent adhesion layer and the second transparent adhesion layer; and forming a second electrode on a second surface of the first semiconductor stack layer.

In accordance with the second embodiment of present application, the steps of the manufacture method further include forming a third transparent adhesion layer on the second surface of the first semiconductor stack layer; forming a fourth transparent adhesion layer on the third transparent adhesion layer; and forming a second semiconductor stack layer on the fourth transparent adhesion layer and the second electrode on the second semiconductor stack layer.

The third embodiment of present application is similar to the first embodiment, and the difference is that a first electrode is disposed on the second semiconductor stack layer. The first electrode and the second electrode are both on the same side of the supporting substrate to form a horizontal structure.

The fourth embodiment of present application is similar to the first embodiment, and the difference is that a first transparent adhesion structure includes only the second transparent adhesion layer and a first intermediate layer formed between the adjacent surfaces of the second transparent adhesion layer and the supporting substrate.

The fifth embodiment of present application is similar to the second embodiment, and the difference is that a first transparent adhesion structure includes only the second transparent adhesion layer and a first intermediate layer formed between the adjacent surfaces of the second transparent adhesion layer and the supporting substrate. A second transparent adhesion structure includes only the fourth transparent adhesion layer and a second intermediate layer formed between the adjacent surfaces of the fourth transparent adhesion layer and the first semiconductor stack layer.

### BRIEF DESCRIPTION OF THE DRAWINGS

The drawings are used to promote the realization of the present application and are a part of the specification. The embodiments shown in the drawings cooperate with the explanation in the“detailed description of preferred embodiments” part in the specification to illustrate the principle of the present application.

FIGS. 1A-1B illustrate cross-sectional views of the manufacture process in accordance with the first embodiment of the present application.

FIG. 2 illustrates a cross-sectional view of the second embodiment of the present application.

FIG. 3 illustrates a cross-sectional view of the third embodiment of the present application.

FIG. 4 illustrates a cross-sectional view of the fourth embodiment of the present application.

FIG. 5 illustrates a cross-sectional view of the fifth embodiment of the present application.

FIG. 6 illustrates a light generating apparatus using the element produced in accordance with any one of the embodiments in the present application.

FIG. 7 illustrates a backlight module using the element produced in accordance with any one of the embodiments in the present application.

### DETAILED DESCRIPTION OF PREFERRED EMBODIMENTS

The embodiments of present application are described in details hereinafter in accompany with drawings. The same or similar parts will be marked with the same numbers in the specification and in the drawings.

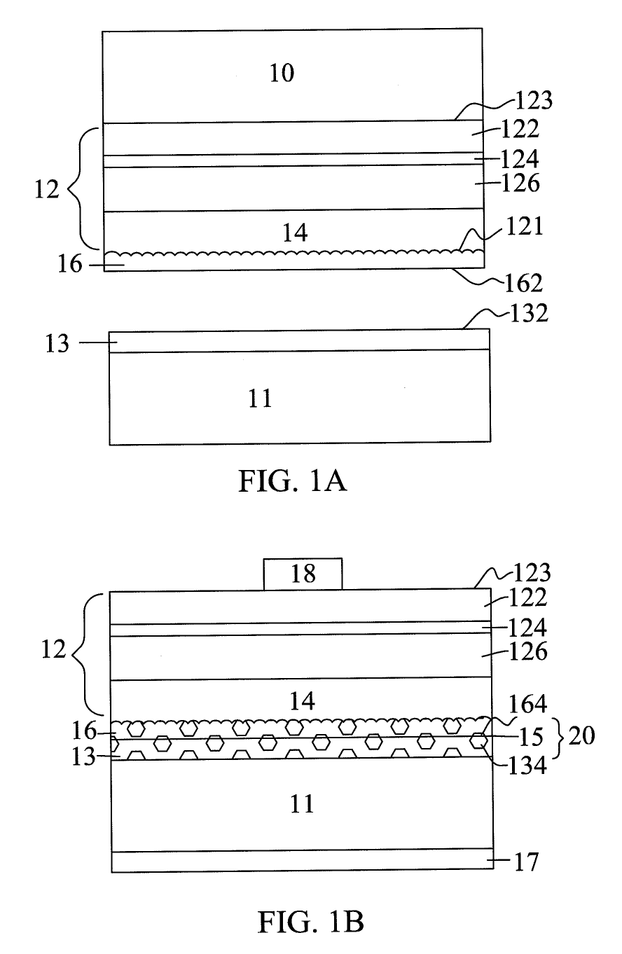

As shown in FIGS. 1A and 1B, a photoelectronic element in the first embodiment includes a growth substrate 10; a first semiconductor stack layer 12 under the growth substrate 10 wherein the first semiconductor stack layer 12 including a window layer 14, a second semiconductor layer 126 between the window layer 14 and the growth substrate 10, a first active layer 124 between the second semiconductor layer 126 and the growth substrate 10, and a first semiconductor layer 122 between the first active layer 124 and the growth substrate 10. Forming a first transparent adhesion layer 13 on a supporting substrate 11 and forming a second transparent adhesion layer 16 under a first surface 121 of the first semiconductor stack layer 12 respectively, and the first surface 121 herein is on the side of the window layer 14. Then, performing a connecting process by placing the supporting substrate 11 with the first transparent adhesion layer 13 thereon and the first semiconductor stack layer 12 with the second transparent adhesion layer 16 thereunder into a reaction chamber, and connecting the first semiconductor stack layer 12 and the supporting substrate 11 by the first transparent adhesion layer 13 and the second transparent adhesion layer 16. After removing the growth substrate 10, a first electrode 17 and a second electrode 18 are formed under the supporting substrate 11 and on the first semiconductor layer 122 respectively.

The supporting substrate 11 is used for supporting the semiconductor structures disposed thereon, and can be an electrically conductive material, a thermally conductive material, and/or an electrically insulative material, such as copper (Cu), aluminum (Al), indium (In), tin (Sn), gold (Au), platinum (Pt), zinc (Zn), silver (Ag), titanium (Ti), lead (Pb), palladium (Pd), germanium (Ge), nickel (Ni), chromium (Cr), cadmium (Cd), cobalt (Co), manganese (Mn), antimony (Sb), bismuth (Bi), gallium (Ga), thallium (Tl), arsenic (As), tellurium (Te), polonium (Po), Iridium (Ir), rhenium (Re), rhodium (Rh), osmium (Os), tungsten (W), lithium (Li), sodium (Na), potassium (K), beryllium (Be), magnesium (Mg), calcium (Ca), strontium (Sr), barium (Ba), zirconium (Zr), molybdenum (Mo), lanthanum (La), copper-tin (Cu—Sn), copper-zinc (Cu—Zn), copper-cadmium (Cu—Cd), tin-lead-antimony (Sn—Pb—Sb), tin-lead-zinc (Sn—Pb—Zn), nickel-tin (Ni—Sn), nickel-cobalt (Ni—Co), gold alloy (Au alloy), gallium phosphide (GaP), gallium arsenide phosphide (GaAsP), gallium arsenide (GaAs), aluminum gallium arsenide (AlGaAs), gallium nitride (GaN), zinc selenide (ZnSe), gold tin (AuSn), indium silver (InAg), indium gold (InAu), gold beryllium (AuBe), gold germanium (AuGe), gold zinc (AuZn), lead tin (PbSn), palladium iridium (PdIn), silicon carbide (SiC), sapphire, diamond, glass, quartz, arcyclic, zinc oxide (ZnO), indium phosphide (InP), lithium gallate (LiGaO₂), lithium aluminate (LiAlO₂), or aluminum nitride (AlN).

The first transparent adhesion layer 13 and the second transparent adhesion layer 16 are used for connecting the first semiconductor stack layer 12 and the supporting substrate 11. The method for forming the first transparent adhesion layer 13 or the second transparent adhesion layer 16 includes processes such as E-beam coating, sputtering, spin coating, physical vapor deposition (PVD), chemical vapor deposition (CVD), vapor phase epitaxy (VPE), liquid phase epitaxy (LPE), molecular beam epitaxy (MBE), metalorganic chemical vapor deposition (MOCVD), metalorganic vapor phase epitaxy (MOVPE), plasma-enhanced chemical vapor deposition (PECVD), thermal coating, or the combination thereof. The material of the first transparent adhesion layer 13 and/or the second transparent adhesion layer 16 could be an electrically conductive material such as indium tin oxide (ITO), indium oxide (InOₓ), tin oxide (SnO), cadmium tin oxide (CTO), antimony tin oxide (ATO), zinc oxide (ZnO), magnesium oxide (MgO), aluminum gallium arsenide (AlGaAs), gallium nitride (GaN), gallium phosphide (GaP), aluminum doped zinc oxide (AZO), zinc tin oxide (ZTO), gallium arsenide (GaAs), gallium arsenide phosphide (GaAsP); organic adhesive material; or an electrically insulative material such as the dielectric material, photoresist, SUB, benzocyclobutene (BCB), perfluorocyclobutane (PFCB), epoxy resin (Epoxy), acrylic resin, cycloolefin copolymer (COC), poly(methyl methacrylate) (PMMA), poly(ethylene terephthalate) (PET), polycarbonate (PC), poly(etherimide) (PEI), fluorocarbon polymer, silicone, glass, aluminum oxide (Al₂O₃), titanium dioxide (TiO₂), silicon nitride (SiNₓ), Silicon-On-Glass (SOG), or tetraethyl orthosilane (TEOS). The material of the first transparent adhesion layer 13 and the second transparent adhesion layer 16 could be the same or different. The first transparent adhesion layer 13 or the second transparent adhesion layer 16 can include a plurality of sub-layers in order to form a distributed Bragg reflector (DBR). Besides, the first transparent adhesion layer 13 or the second transparent adhesion layer 16 can be a transparent conductive layer. As shown in FIG. 1B, the first transparent adhesion layer 13 or the second transparent adhesion layer 16 further includes a plurality of cavities 134 and 164, and the plurality of cavities 134 and 164 can include at least air or the gas originally from the reaction chamber, such as oxygen (O₂), nitrogen (N₂), hydrogen (H₂), helium (He), argon (Ar), xenon (Xe), carbon dioxide (CO₂), methane (CH₄), silane (SiH₄), nitrous oxide (N₂O), or ammonia (NH₃) therein.

Before connecting the first transparent adhesion layer 13 and the second transparent adhesion layer 16, the surfaces of the first transparent adhesion layer 13 or the second transparent adhesion layer 16 are flatted. The method for flattening can be chemical mechanical polishing (CMP), and the surface roughness of the surface of the first transparent adhesion layer 13 or the second transparent adhesion layer 16 is less than 2 nm after flatted. Then, treating the flatted surfaces 132 and 162 of the first transparent adhesion layer 13 and the second transparent adhesion layer 16 with an activator to make the surfaces 132 and 162 contain hydrogen-oxygen bonds or hydrogen bonds, and the duration of the treatment is not less than 1 minute. The method for the treatment can be immersion, coating, and/or plasma treatment. Another method for forming the surfaces containing hydrogen-oxygen bonds or hydrogen bonds can be to mix the particles of the materials of the first transparent adhesion layer 13 and the second transparent adhesion layer 16 and the activator in a weight ratio of about one to four as a solution and then stir. Wherein the diameter of the particle is less than 200 nm, the better is less than 100 nm, and the best is less than 10 nm. The stirring duration is not less than 1 hour, and the better is 3 hours. Then, coating the solution on the supporting substrate 11 or under the first surface 121 of the first semiconductor stack layer 12 to form the first transparent adhesion layer 13 and the second transparent adhesion layer 16, wherein the surfaces of the first transparent adhesion layer 13 and the second transparent adhesion layer 16 contain hydrogen-oxygen bonds or hydrogen bonds. The material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof. And then, the surfaces 132 and 162 of the first transparent adhesion layer 13 and the second transparent adhesion layer 16 are in contact with each other by a connecting process to form a first transparent adhesion structure 20. The environmental temperature of the connecting process is between 200° C. and 700° C., and is better between 300° C. and 600° C., the environmental pressure of the connecting process is about 3 kg/cm^{2 ˜25} kg/cm², and the duration for the connecting process is not less than 2 hours. After connecting the first transparent adhesion layer 13 and the second transparent adhesion layer 16, a first intermediate layer 15 is formed to be adjacent to the surfaces of the first transparent adhesion layer 13 and the second transparent adhesion layer 16 to raise the adhesive strength between the first transparent adhesion layer 13 and the second transparent adhesion layer 16, and wherein the first intermediate layer 15 includes the oxygen element.

The refractive index of the window layer 14 is different from that of the second semiconductor layer 126, and it causes the light scattering and raises the light extraction efficiency. The material of the window layer 14 is such as indium tin oxide (ITO), indium oxide (InOₓ), tin oxide (SnO), cadmium tin oxide (CTO), antimony tin oxide (ATO), aluminum doped zinc oxide (AZO), zinc tin oxide (ZTO), zinc oxide (ZnO), aluminum gallium arsenide (AlGaAs), gallium nitride (GaN), gallium phosphide (GaP), gallium arsenide (GaAs), or gallium arsenide phosphide (GaAsP), and the window layer 14 further includes a rough surface 121. The first semiconductor stack layer 12 is used to produce or absorb light, and the material of the first semiconductor stack layer 12 includes one or more than one elements selected from the group consisting of gallium (Ga), aluminum (Al), indium (In), arsenic (As), phosphorus (P), nitrogen (N), zinc (Zn), selenium (Se), antimony (Sb), cadmium (Cd), tellurium (Te), mercury (Hg), sulfur (S), hydrogen (H), magnesium (Mg), tin (Sn), boron (B), lead (Pb), carbon (C), and silicon (Si), wherein the first semiconductor layer 122 and the second semiconductor layer 126 have different electrical properties. The first semiconductor stack layer 12 could optionally include the window layer 14, and if there is no window layer, the first surface 121 could be a rough surface located on a side of the second semiconductor layer 126. Besides, the window layer 14 also could be located on the first semiconductor layer 122 to raise the light extraction efficiency.

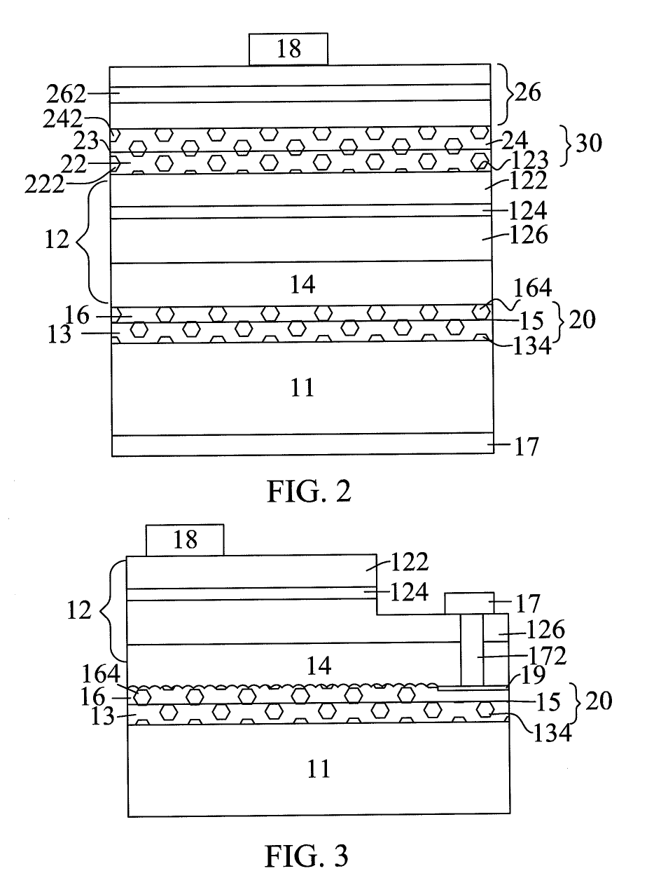

As shown in FIG. 2, the second embodiment is similar to the first embodiment. The difference is at least that the second embodiment further includes a third transparent adhesion layer 22, which can be a rough surface, located on a second surface 123 which is on the side of the first semiconductor layer 122b of the first semiconductor stack layer 12; a fourth transparent adhesion layer 24 located on the third transparent adhesion layer 22; and a second semiconductor stack layer 26 located on the fourth transparent adhesion layer 24, wherein the second semiconductor stack layer 26 includes a second active layer 262. The second electrode 18 is located on the second semiconductor stack layer 26.

The third transparent adhesion layer 22 and the fourth transparent adhesion layer 24 are used to connect the first semiconductor stack layer 12 and the second semiconductor layer 26, and the method for forming the third transparent adhesion layer 22 or the fourth transparent adhesion layer 24 includes the processes such as E-beam coating, sputtering, spin coating, physical vapor deposition (PVD), chemical vapor deposition (CVD), vapor phase epitaxy (VPE), liquid phase epitaxy (LPE), molecular beam epitaxy (MBE), metalorganic chemical vapor deposition (MOCVD), metalorganic vapor phase epitaxy (MOVPE), plasma-enhanced chemical vapor deposition (PECVD), thermal coating, or the combination thereof. The material of the third transparent adhesion layer 22 and/or the fourth transparent adhesion layer 24 could be an electrically conductive material such as indium tin oxide (ITO), indium oxide (InOₓ), tin oxide (SnO), cadmium tin oxide (CTO), antimony tin oxide (ATO), zinc oxide (ZnO), magnesium oxide (MgO), aluminum gallium arsenide (AlGaAs), gallium nitride (GaN), gallium phosphide (GaP), aluminum doped zinc oxide (AZO), zinc tin oxide (ZTO), gallium arsenide (GaAs), gallium arsenide phosphide (GaAsP); organic adhesive material; or an electrically insulating material such as the dielectric material, photoresist, SU8, benzocyclobutene (BCB), perfluorocyclobutane (PFCB), epoxy resin (Epoxy), acrylic resin, cycloolefin copolymer (COC), poly(methyl methacrylate) (PMMA), poly(ethylene terephthalate) (PET), polycarbonate (PC), poly(etherimide) (PEI), fluorocarbon polymer, silicone, glass, aluminum oxide (Al₂O₃), titanium dioxide (TiO₂), silicon nitride (SiNₓ), Silicon-On-Glass (SOG), or tetraethyl orthosilane (TEOS). The material of the third transparent adhesion layer 22 and the fourth transparent adhesion layer 24 can be the same or different. The third transparent adhesion layer 22 or the fourth transparent adhesion layer 24 can include a plurality of sub-layers in order to form a distributed Bragg reflector (DBR). Besides, the third transparent adhesion layer 22 or the fourth transparent adhesion layer 24 can be a transparent conductive layer. The third transparent adhesion layer 22 or the fourth transparent adhesion layer 24 further includes a plurality of cavities 222 and 242, and the plurality of cavities 222 and 242 can include at least air or the gas originally from the reaction chamber such as oxygen (O₂), nitrogen (N₂), hydrogen (H₂), helium (He), argon (Ar), xenon (Xe), carbon dioxide (CO₂), methane (CH₄), silane (SiH4), nitrous oxide (N₂O), or ammonia (NH₃) therein.

Before connecting the third transparent adhesion layer 22 and the fourth transparent adhesion layer 24, the surfaces of the third transparent adhesion layer 22 or the fourth transparent adhesion layer 24 are flatted. The method for flattening can be chemical mechanical polishing (CMP), and the surface roughness of the surface of the third transparent adhesion layer 22 or the second transparent adhesion layer 24 is less than 2 nm after flatted. Then, treating the flatted surfaces of the third transparent adhesion layer 22 and the fourth transparent adhesion layer 24 with an activator to make the surfaces contain hydrogen-oxygen bonds or hydrogen bonds, and the duration of the treatment is not less than 1 minute. The method for the treatment can be immersion, coating, and/or plasma treatment. Another method for forming the surfaces containing hydrogen-oxygen bonds or hydrogen bonds can be to mix the particles of the materials of the third transparent adhesion layer 22 and the fourth transparent adhesion layer 24 and the activator in a weight ratio of about one to four as a solution and then stir. Wherein the diameter of the particle is less than 200 nm, the better is less than 100 nm, and the best is less than 10 nm. The stirring duration is not less than 1 hour, and the better is 3 hours. Then, coating the solution on the second surface 123 of the first semiconductor stack layer 12 or under the surface where the second semiconductor stack layer 26 adjacent to the first semiconductor stack layer 12 to form the third transparent adhesion layer 22 and the fourth transparent adhesion layer 24, wherein the surfaces of the third transparent adhesion layer 22 and the fourth transparent adhesion layer 24 contain hydrogen-oxygen bonds or hydrogen bonds. The material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof. And then, the surfaces of the third transparent adhesion layer 22 and the fourth transparent adhesion layer 24 are in contact with each other by a connecting process to form a second transparent adhesion structure 30. The environmental temperature of the connecting process is between 200° C. and 700° C., and is better between 300° C. and 600° C., the environmental pressure of the connecting process is about 3 kg/cm^{2 ˜25} kg/cm², and the duration for the connecting process is not less than 2 hours. After connecting the third transparent adhesion layer 22 and the fourth transparent adhesion layer 24, a second intermediate layer 23 is formed to be adjacent to the surfaces of the third transparent adhesion layer 22 and the fourth transparent adhesion layer 24 to raise the adhesive strength between the third transparent adhesion layer 22 and the fourth transparent adhesion layer 24, and wherein the second intermediate layer 23 includes the oxygen element. The second semiconductor stack layer 26 is used to produce or absorb light, and the material of the second semiconductor stack layer 26 includes one or more than one elements selected from the group consisting of gallium (Ga), aluminum (Al), indium (In), arsenic (As), phosphorus (P), nitrogen (N), zinc (Zn), selenium (Se), antimony (Sb), cadmium (Cd), tellurium (Te), mercury (Hg), sulfur (S), hydrogen (H), magnesium (Mg), tin (Sn), boron (B), lead (Pb), carbon (C), and silicon (Si).

As shown in FIG. 3, the third embodiment is similar to the first embodiment. The difference is at least that the first electrode 17 is disposed on the second semiconductor layer 126. The first electrode 17 and the second electrode 18 are both on the same side of the supporting substrate 11 to form a horizontal structure. Besides, the first electrode 17 can optionally include a connecting part 172, which connects the first electrode 17 and a conductive part 19. The conductive part 19 is located between the window layer 14 and the second transparent adhesion layer 16 and is used to conduct current. The material of the connecting part 172 or the conductive part 19 can be copper (Cu), aluminum (Al), indium (In), tin (Sn), gold (Au), platinum (Pt), zinc (Zn), silver (Ag), titanium (Ti), lead (Pb), palladium (Pd), germanium (Ge), nickel (Ni), chromium (Cr), cadmium (Cd), cobalt (Co), manganese (Mn), antimony (Sb), bismuth (Bi), gallium (Ga), thallium (Tl), arsenic (As), tellurium (Te), polonium (Po), Iridium (Ir), rhenium (Re), rhodium (Rh), osmium (Os), tungsten (W), lithium (Li), sodium (Na), potassium (K), beryllium (Be), magnesium (Mg), calcium (Ca), strontium (Sr), barium (Ba), zirconium (Zr), molybdenum (Mo), lanthanum (La), copper-tin (Cu—Sn), copper-zinc (Cu—Zn), copper-cadmium (Cu—Cd), tin-lead-antimony (Sn—Pb—Sb), tin-lead-zinc (Sn—Pb—Zn), nickel-tin (Ni—Sn), nickel-cobalt (Ni—Co), gold alloy (Au alloy), gallium phosphide (GaP), gallium arsenide phosphide (GaAsP), gallium arsenide (GaAs), aluminum gallium arsenide (AlGaAs), gallium nitride (GaN), zinc selenide (ZnSe), gold tin (AuSn), indium silver (InAg), indium gold (InAu), gold beryllium (AuBe), gold germanium (AuGe), gold zinc (AuZn), lead tin (PbSn), palladium iridium (PdIn) or the combination thereof. Besides, the first electrode 17 also can be located on the window layer 14.

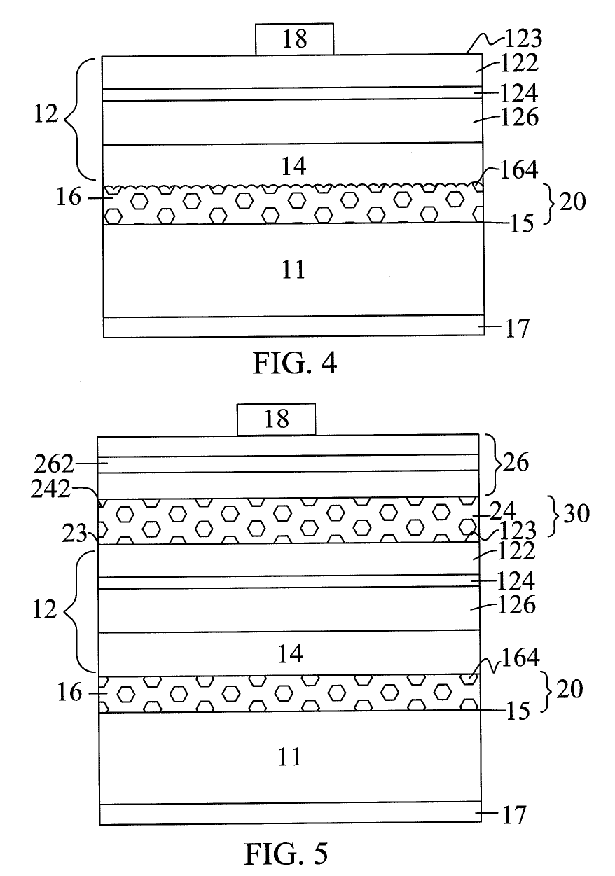

As shown in FIG. 4, the fourth embodiment is similar to the first embodiment. The difference is at least that the first transparent adhesion structure 20 includes only the second transparent adhesion layer 16 and the first intermediate layer 15 located between the adjacent surfaces of the second transparent adhesion layer 16 and the supporting substrate 11. Before connecting the supporting substrate 11 and the second transparent adhesion layer 16, the surface where the supporting substrate 11 adjacent to the second transparent adhesion layer 16 or the surface 162 of the second transparent adhesion layer 16 is flatted. The method for flattening can be chemical mechanical polishing (CMP), and the surface roughness of the surface where the supporting substrate 11 adjacent to the second transparent adhesion layer 16 or the surface 162 of the second transparent adhesion layer 16 is less than 2 nm after being flatted. Then, treating the flatted surface where the supporting substrate 11 adjacent to the second transparent adhesion layer 16 and the surface 162 of the second transparent adhesion layer 16 with an activator to make the surface where the supporting substrate 11 adjacent to the second transparent adhesion layer 16 or the surface 162 of the second transparent adhesion layer 16 contain hydrogen-oxygen bonds or hydrogen bonds, and the duration of the treatment is not less than 1 minute. The method for the treatment can be immersion, coating, and/or plasma treatment. Another method for forming the surfaces containing hydrogen-oxygen bonds or hydrogen bonds can be to mix the particles of the materials of the second transparent adhesion layer 16 and the activator in a weight ratio of about one to four as a solution and then stir. Wherein the diameter of the particle is less than 200 nm, the better is less than 100 nm, and the best is less than 10 nm. The stirring duration is not less than 1 hour, and the better is 3 hours. Then, coating the solution under the first surface 121 to form the second transparent adhesion layer 16, wherein the surface 162 of the second transparent adhesion layer 16 contains hydrogen-oxygen bonds or hydrogen bonds. The material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof. And then, the supporting substrate 11 and the second transparent adhesion layer 16 are in contact with each other by a connecting process. The environmental temperature of the connecting process is between 200° C. and 700° C., and is better between 300° C. and 600° C., the environmental pressure of the connecting process is about 3 kg/cm² to 25 kg/cm², and the duration for the connecting process is not less than 2 hours.

As shown in FIG. 5, the fifth embodiment is similar to the second embodiment. The difference is at least that the first transparent adhesion structure 20 includes only the second transparent adhesion layer 16 and the first intermediate layer 15 located between the adjacent surfaces of the second transparent adhesion layer 16 and the supporting substrate 11, and the second transparent adhesion structure 30 includes only the fourth transparent adhesion layer 24 and the second intermediate layer 23 located between the adjacent surfaces of the fourth transparent adhesion layer 24 and the first semiconductor stack layer 12. Before connecting the first semiconductor stack layer 12 and the fourth transparent adhesion layer 24, the second surface 123 of the first semiconductor stack layer 12 or the surface where the fourth transparent adhesion layer 24 adjacent to the first semiconductor adhesion layer 12 is flatted. The method for flattening can be chemical mechanical polishing (CMP), and the surface roughness of the second surface 123 or the surface where the fourth transparent adhesion layer 24 adjacent to the first semiconductor adhesion layer 12 is less than 2 nm after flatted. Then, treating the flatted the second surface 123 or the surface where the fourth transparent adhesion layer 24 adjacent to the first semiconductor adhesion layer 12 with an activator to make the second surface 123 or the surface where the fourth transparent adhesion layer 24 adjacent to the first semiconductor adhesion layer 12 containing hydrogen-oxygen bonds or hydrogen bonds, and the duration of the treatment is not less than 1 minute. The method for the treatment can be immersion, coating, and/or plasma treatment. Another method for forming the surfaces containing hydrogen-oxygen bonds or hydrogen bonds can be to mix the particles of the materials of the fourth transparent adhesion layer 24 and the activator in a weight ratio of about one to four as a solution and then stir. Wherein the diameter of the particle is less than 200 nm, the better is less than 100 nm, and the best is less than 10 nm. The stirring duration is not less than 1 hour, and the better is 3 hours. Then, coating the solution on the surface where the second semiconductor stack layer 26 adjacent to the first semiconductor stack layer 12 to form the fourth transparent adhesion layer 24, wherein the surface of the fourth transparent adhesion layer 24 containing hydrogen-oxygen bonds or hydrogen bonds. The material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof. And then, the fourth transparent adhesion layer 24 and the first semiconductor stack layer 12 are in contact with each other by a connecting process. The environmental temperature of the connecting process is between 200° C. and 700° C., and is better between 300° C. and 600° C., the environmental pressure of the connecting process is about 3 kg/cm² to 25 kg/cm², and the duration for the connecting process is not less than 2 hours.

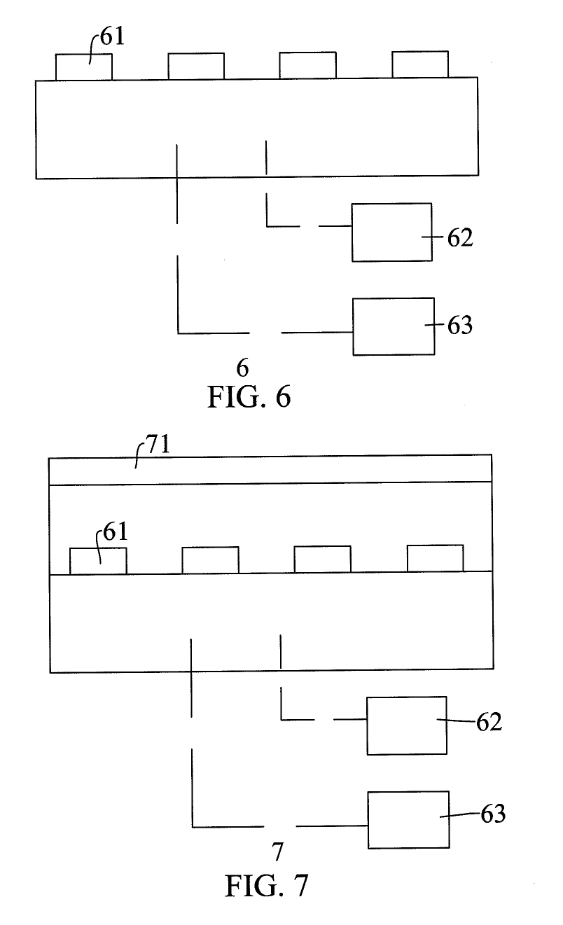

FIG. 6 illustrates a light generating apparatus 6 including the LED dies in accordance with any embodiment in the present application. The light generating apparatus 6 can be a lighting apparatus such as the street light, the car lamp, or the indoor illumination system, and also can be the traffic signal, or the light source in the backlight module of a flat display. The light generating apparatus 6 includes a light source 61 which is composed of the aforementioned photoelectronic element, a power supply system 62 used to provide the current to the light source 61, and a controlling system 63 used to control the power supply system 62.

FIG. 7 illustrates a cross-sectional view of a backlight module. The backlight module 7 includes the light generating apparatus 6 aforementioned and a photoelectronic element 71. The photoelectronic element 71 could convert the light generating from the light generating apparatus to make the light suitable for applying in the flat display, such as scattering the light generating from the light generating apparatus 6.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A method of forming a photoelectronic element with a transparent adhesion structure, comprising:
providing a first semiconductor stack layer including a first active layer;
providing a supporting substrate;
forming a transparent adhesion layer under the first semiconductor stack layer having a surface containing hydrogen-oxygen bonds or hydrogen bonds; and
performing a first connecting process to connect the first semiconductor stack layer and the supporting substrate by the transparent adhesion layer under the first semiconductor stack layer.

2. The method of forming a photoelectronic element with a transparent adhesion structure of claim 1, after the first connecting process, further comprising:
providing a second semiconductor stack layer including a second active layer;
forming another transparent adhesion layer under the second semiconductor stack layer having a surface containing hydrogen-oxygen bonds or hydrogen bonds; and
performing a second connecting process to connect the first semiconductor stack layer and the second semiconductor stack layer by the transparent adhesion layer under the second semiconductor stack layer.

3. The method of forming a photoelectronic element with a transparent adhesion structure of claim 2, before performing the second connecting process, further comprising:
flattening the surface of the transparent adhesion layer under the second semiconductor stack layer; and
treating the flatted surface of the transparent adhesion layer under the second semiconductor stack layer by an activator.

4. The method of forming a photoelectronic element with a transparent adhesion structure of claim 1, before performing the first connecting process, further comprising:
flattening the surface of the transparent adhesion layer under the first semiconductor stack layer; and
treating the flatted surface of the transparent adhesion layer under the first semiconductor stack layer by an activator.

5. The method of forming a photoelectronic element with a transparent adhesion structure of claim 3, wherein the method of flattening the transparent adhesion layer under the second semiconductor stack layer is chemical mechanical polishing (CMP).

6. The method of forming a photoelectronic element with a transparent adhesion structure of claim 4, wherein the method of flattening the transparent adhesion layer under the first semiconductor stack layer is chemical mechanical polishing (CMP).

7. The method of forming a photoelectronic element with a transparent adhesion structure of claim 3, wherein the surface roughness of the flatted surface of the transparent adhesion layer under the second semiconductor stack layer is less than 2 nm.

8. The method of forming a photoelectronic element with a transparent adhesion structure of claim 4, wherein the surface roughness of the flatted surface of the transparent adhesion layer under the first semiconductor stack layer is less than 2 nm.

9. The method of forming a photoelectronic element with a transparent adhesion structure of claim 3, wherein the method of treating the flatted surface of the transparent adhesion layer under the second semiconductor stack layer by the activator including immersion, coating, and/or plasma treatment and the duration for treating the flatted surface of the transparent adhesion layer under the second semiconductor stack layer by the activator is not less than 1 minute.

10. The method of forming a photoelectronic element with a transparent adhesion structure of claim 4, wherein the method of treating the flatted surface of the transparent adhesion layer under the first semiconductor stack layer by the activator including immersion, coating, and/or plasma treatment and the duration for treating the flatted surface of the transparent adhesion layer under the second semiconductor stack layer by the activator is not less than 1 minute.

11. The method of forming a photoelectronic element with a transparent adhesion structure of claim 2, wherein the environmental temperature for the first connecting process or the second connecting process is between 200° C. and 700° C., the environmental pressure for the first connecting process or the second connecting process is between 3 kg/cm² and 25 kg/cm², or the duration for the first connecting process or the second connecting process is not less than 2 hours.

12. The method of forming a photoelectronic element with a transparent adhesion structure of claim 2, wherein the method of forming the transparent adhesion layer under the first semiconductor stack layer or the transparent adhesion layer under the second semiconductor stack layer including:
providing material particles of the transparent adhesion layer under the first semiconductor stack layer or the transparent adhesion layer under the second semiconductor stack layer;
mixing an activator and the material particles to make a solution; and
providing the solution under the first semiconductor stack layer or on the second semiconductor stack layer to form the transparent adhesion layer under the first semiconductor stack layer or the transparent adhesion layer under the second semiconductor stack layer.

13. The method of forming a photoelectronic element with a transparent adhesion structure of claim 12, wherein the diameter of the material particle is less than 200 nm.

14. The method of forming a photoelectronic element with a transparent adhesion structure of claim 12, wherein the weight ratio of the activator and the material particles in the solution is about one to four.

15. The method of forming a photoelectronic element with a transparent adhesion structure of claim 12, after mixing the activator and the material particles, stirring the solution and the duration for stirring the solution is not less than 1 hour.

16. The method of forming a photoelectronic element with a transparent adhesion structure of claim 3, the material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof.

17. The method of forming a photoelectronic element with a transparent adhesion structure of claim 4, the material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof.

18. The method of forming a photoelectronic element with a transparent adhesion structure of claim 12, the material of the activator can be sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof.

19. A method of forming a photoelectronic element with a transparent adhesion structure, comprising:
providing a first semiconductor stack layer including a first surface, a second surface, and a first active layer;
providing a supporting substrate;
forming a first transparent adhesion layer on the supporting substrate and a second transparent adhesion layer under the first surface of the first semiconductor stack layer respectively, wherein at least one surface of the first transparent adhesion layer or of the second transparent adhesion layer containing hydrogen-oxygen bonds or hydrogen bonds; and
performing a first connecting process to connect the first semiconductor stack layer and the supporting substrate by the first transparent adhesion layer and the second transparent adhesion layer.

20. The method of forming a photoelectronic element with a transparent adhesion structure of claim 19, after the first connecting process, further comprising:
providing a second semiconductor stack layer including a second active layer;
forming a third transparent adhesion layer on the second surface of the first semiconductor stack layer and a fourth transparent adhesion layer under the second semiconductor stack layer, and a surface of the third transparent adhesion layer or of the fourth transparent adhesion layer containing hydrogen-oxygen bonds or hydrogen bonds; and
performing a second connecting process to connect the first semiconductor stack layer and the second semiconductor stack layer by the third transparent adhesion layer and the fourth transparent adhesion layer.

21. The method of forming a photoelectronic element with a transparent adhesion structure of claim 19, wherein the method of forming the first transparent adhesion layer or the second transparent adhesion layer including the processes such as E-beam coating, sputtering, spin coating, physical vapor deposition (PVD), chemical vapor deposition (CVD), vapor phase epitaxy (VPE), liquid phase epitaxy (LPE), molecular beam epitaxy (MBE), metalorganic chemical vapor deposition (MOCVD), metalorganic vapor phase epitaxy (MOVPE), plasma-enhanced chemical vapor deposition (PECVD), thermal coating, or the combination thereof.

22. The method of forming a photoelectronic element with a transparent adhesion structure of claim 20, wherein the method of forming the first transparent adhesion layer, the second transparent adhesion layer, the third transparent adhesion layer, or the fourth transparent adhesion layer including processes such as E-beam coating, sputtering, spin coating, physical vapor deposition (PVD), chemical vapor deposition (CVD), vapor phase epitaxy (VPE), liquid phase epitaxy (LPE), molecular beam epitaxy (MBE), metalorganic chemical vapor deposition (MOCVD), metalorganic vapor phase epitaxy (MOVPE), plasma-enhanced chemical vapor deposition (PECVD), thermal coating, or the combination thereof.

23. The method of forming a photoelectronic element with a transparent adhesion structure of claim 19, before performing the first connecting process, further comprising:
flattening the surface of the first transparent adhesion layer or of the second transparent adhesion layer; and
treating the flatted surface of the first transparent adhesion layer or of the second transparent adhesion layer by an activator.

24. The method of forming a photoelectronic element with a transparent adhesion structure of claim 23, wherein the method of flattening the first transparent adhesion layer or the second transparent adhesion layer including chemical mechanical polishing (CMP).

25. The method of forming a photoelectronic element with a transparent adhesion structure of claim 23, wherein the surface roughness of the flatted surface of the first transparent adhesion layer or of the second transparent adhesion layer is less than 2 nm.

26. The method of forming a photoelectronic element with a transparent adhesion structure of claim 23, wherein the method of treating the flatted surface of the first transparent adhesion layer or the second transparent adhesion layer by the activator including immersion, coating, and/or plasma treatment and the duration for treating the flatted surface of the first transparent adhesion layer or the second transparent adhesion layer by the activator is not less than 1 minute.

27. The method of forming a photoelectronic element with a transparent adhesion structure of claim 20, wherein the environmental temperature for the first connecting process or the second connecting process is between 200° C. and 700° C., the environmental pressure for the first connecting process or the second connecting process is between 3 kg/cm² and 25 kg/cm², or the duration for the first connecting process or the second connecting process is not less than 2 hours.

28. The method of forming a photoelectronic element with a transparent adhesion structure of claim 19, wherein the method of forming the first transparent adhesion layer or the second transparent adhesion layer including:
providing material particles of the first transparent adhesion layer or the second transparent adhesion layer;
mixing an activator and the material particles to make a solution; and
providing the solution on the supporting substrate or under the first surface to form the first transparent adhesion layer or the second transparent adhesion layer.

29. The method of forming a photoelectronic element with a transparent adhesion structure of claim 28, wherein the diameter of the material particle is less than 200 nm.

30. The method of forming a photoelectronic element with a transparent adhesion structure of claim 28, wherein the weight ratio of the activator and the material particles in the solution is about one to four.

31. The method of forming a photoelectronic element with a transparent adhesion structure of claim 28, after mixing the activator and the material particles, stirring the solution, and the duration for stirring the solution is not less than 1 hour.

32. The method of forming a photoelectronic element with a transparent adhesion structure of claim 23, the material of the activator including sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof.

33. The method of forming a photoelectronic element with a transparent adhesion structure of claim 28, the material of the activator including sulfuric acid (H₂SO₄), hydrochloric acid (HCl), nitric acid (HNO₃), acetic acid (CH₃COOH), potassium carbonate (K₂CO₃), potassium sulfide (K₂S), potassium phosphate (K₃PO₄), sodium nitrate (NaNO₃), ammonium hydroxide (NH₄OH), sodium hydroxide (NaOH), potassium hydroxide (KOH), hydrogen (H₂), oxygen (O₂), hydroperoxide (H₂O₂), or the combination thereof.

34. The method of forming a photoelectronic element with a transparent adhesion structure of claim 19 further comprising providing a growth substrate, wherein the first semiconductor stack layer formed on the growth substrate.

35. A photoelectronic element with a transparent adhesion structure, comprising:
a supporting substrate;
a transparent adhesion layer on the supporting substrate; and
a first semiconductor stack layer including a first active layer on the second transparent adhesion layer; wherein one surface of the surfaces where the transparent adhesion layer on the supporting substrate adjacent to the supporting substrate having the surface roughness less than 2 nm and one surface of the surfaces where the transparent adhesion layer on the supporting substrate adjacent to the supporting substrate containing hydrogen-oxygen bonds or hydrogen bonds.

36. The photoelectronic element with a transparent adhesion structure on the supporting substrate of claim 35, further comprising a first intermediate layer including the oxygen element between the adjacent surfaces of the supporting substrate and the transparent adhesion layer on the supporting substrate.

37. The photoelectronic element with a transparent adhesion structure on the supporting substrate of claim 35, further comprising:
a transparent adhesion layer on the first semiconductor stack layer; and a second semiconductor stack layer including a second active layer on the transparent adhesion layer on the first semiconductor stack layer.

38. The photoelectronic element with a transparent adhesion structure on the supporting substrate and a transparent adhesion structure on the first semiconductor stack layer of claim 37, wherein the transparent adhesion layer on the supporting substrate or the transparent adhesion layer on the first semiconductor stack layer including a plurality of cavities.

39. The photoelectronic element with a transparent adhesion structure on the supporting substrate and a transparent adhesion structure on the first semiconductor stack layer of claim 38, wherein the plurality of cavities containing the gas comprising oxygen (O₂), nitrogen (N₂), hydrogen (H₂), helium (He), argon (Ar), xenon (Xe), carbon dioxide (CO₂), methane (CH₄), silane (SiH₄), nitrous oxide (N₂O), ammonia (NH₃), or the combination thereof.

40. The photoelectronic element with a transparent adhesion structure on the supporting substrate of claim 35, wherein the transparent adhesion layer on the supporting substrate including one or more than one material comprising an electrically conductive material, an organic adhesive material, or an electrically insulative material.

41. The photoelectronic element with a transparent adhesion structure on the supporting substrate of claim 40, wherein the electrically conductive material comprising indium tin oxide (ITO), indium oxide (InOₓ), tin oxide (SnO), cadmium tin oxide (CTO), antimony tin oxide (ATO), zinc oxide (ZnO), magnesium oxide (MgO), aluminum gallium arsenide (AlGaAs), gallium nitride (GaN), gallium phosphide (GaP), aluminum doped zinc oxide (AZO), zinc tin oxide (ZTO), gallium arsenide (GaAs), or gallium arsenide phosphide (GaAsP).

42. The photoelectronic element with a transparent adhesion structure on the supporting substrate of claim 40, wherein the electrically insulative material comprising the dielectric material, photoresist SUB, benzocyclobutene (BCB), perfluorocyclobutane (PFCB), epoxy resin (Epoxy), acrylic resin, cycloolefin copolymer (COC), poly(methyl methacrylate) (PMMA), poly(ethylene terephthalate) (PET), polycarbonate (PC), poly(etherimide) (PEI), fluorocarbon polymer, silicone, glass, aluminum oxide (Al₂O₃), titanium dioxide (TiO₂), silicon nitride (SiNₓ), Silicon-On-Glass (SOG), or tetraethyl orthosilane (TEOS).

43. The photoelectronic element with a transparent adhesion structure on the supporting substrate and a transparent adhesion structure on the first semiconductor stack layer of claim 37, wherein the transparent adhesion layer on the supporting substrate or the transparent adhesion layer on the first semiconductor stack layer including one or more than one material comprising an electrically conductive material, an organic adhesive material, or an electrically insulative material.

44. The photoelectronic element with a transparent adhesion structure on the supporting substrate and a transparent adhesion structure on the first semiconductor stack layer of claim 43, wherein the electrically conductive material comprising indium tin oxide (ITO), indium oxide (InOₓ), tin oxide (SnO), cadmium tin oxide (CTO), antimony tin oxide (ATO), zinc oxide (ZnO), magnesium oxide (MgO), aluminum gallium arsenide (AlGaAs), gallium nitride (GaN), gallium phosphide (GaP), aluminum doped zinc oxide (AZO), zinc tin oxide (ZTO), gallium arsenide (GaAs), or gallium arsenide phosphide (GaAsP).

45. The photoelectronic element with a transparent adhesion structure on the supporting substrate and a transparent adhesion structure on the first semiconductor stack layer of claim 43, wherein the electrically insulative material comprising the dielectric material, photoresist SUB, benzocyclobutene (BCB), perfluorocyclobutane (PFCB), epoxy resin (Epoxy), acrylic resin, cycloolefin copolymer (COC), poly(methyl methacrylate) (PMMA), poly(ethylene terephthalate) (PET), polycarbonate (PC), poly(etherimide) (PEI), fluorocarbon polymer, silicone, glass, aluminum oxide (Al₂O₃), titanium dioxide (TiO₂), silicon nitride (SiNₓ), Silicon-On-Glass (SOG), or tetraethyl orthosilane (TEOS).

46. The photoelectronic element with a transparent adhesion structure of claim 35, wherein the transparent adhesion layer on the supporting substrate including a plurality of sub-layers.

47. The photoelectronic element with a transparent adhesion structure on the supporting substrate and a transparent adhesion structure on the first semiconductor stack layer of claim 37, wherein the transparent adhesion layer on the first semiconductor stack layer or the transparent adhesion layer on the first semiconductor stack layer including a plurality of sub-layers.

48. The photoelectronic element with a transparent adhesion structure on the supporting substrate of claim 35, wherein the transparent adhesion layer on the supporting substrate including a distributed Bragg reflector (DBR).

49. The photoelectronic element with a transparent adhesion structure on the supporting substrate and a transparent adhesion structure on the first semiconductor stack layer of claim 37, wherein the transparent adhesion layer on the supporting substrate or the transparent adhesion layer on the first semiconductor stack layer including a distributed Bragg reflector (DBR).

50. The photoelectronic element with a transparent adhesion structure on the supporting substrate of claim 35, wherein the material of the first semiconductor stack layer including one or more than one elements comprising the group consisting of gallium (Ga), aluminum (Al), indium (In), arsenic (As), phosphorus (P), nitrogen (N), zinc (Zn), selenium (Se), antimony (Sb), cadmium (Cd), tellurium (Te), mercury (Hg), sulfur (S), hydrogen (H), magnesium (Mg), tin (Sn), boron (B), lead (Pb), carbon (C), and silicon (Si).

51. The photoelectronic element with a transparent adhesion structure on the supporting substrate and a transparent adhesion structure on the first semiconductor stack layer of claim 37, wherein the material of the first semiconductor stack layer or the second semiconductor stack layer including one or more than one elements comprising the group consisting of gallium (Ga), aluminum (Al), indium (In), arsenic (As), phosphorus (P), nitrogen (N), zinc (Zn), selenium (Se), antimony (Sb), cadmium (Cd), tellurium (Te), mercury (Hg), sulfur (S), hydrogen (H), magnesium (Mg), tin (Sn), boron (B), lead (Pb), carbon (C), and silicon (Si).

52. The photoelectronic element with a transparent adhesion structure on the supporting substrate and a transparent adhesion structure on the first semiconductor stack layer of claim 37, further comprising a second intermediate layer including the oxygen element between the adjacent surfaces of the first semiconductor stack layer and the transparent adhesion layer on the first semiconductor stack layer.
